(19) United States
(12) Patent Application Publication
(10) Pub. No.: US 2012/0205609 A1
(43) Pub. Date: Aug. 16, 2012

(54) MEMORY DEVICE AND METHOD FOR MANUFACTURING THE SAME

(75) Inventors: Shigeto OSHINO, Kanagawa-ken (JP); Kenji Aoyama, Kanagawa-ken (JP); Kazuhiko Yamamoto, Kanagawa-ken (JP); Shinichi Nakao, Kanagawa-ken (JP); Kei Watanabe, Tokyo (JP); Satoshi Ishikawa, Kanagawa-ken (JP)

(73) Assignee: KABUSHIKI KAISHA TOSHIBA, Tokyo (JP)

(21) Appl. No.: 13/235,842

(22) Filed: Sep. 19, 2011

(30) Foreign Application Priority Data
Feb. 16, 2011 (JP) 2011-031326

(51) Int. Cl. H01L 45/00; H01L 21/8239; B82Y 99/00

(52) U.S. Cl. 257/4; 438/381; 977/742; 257/E45.001; 257/E21.645

(57) ABSTRACT

According to one embodiment, a memory device includes a lower electrode layer, a nanomaterial assembly layer, a protective layer and an upper electrode layer. The nanomaterial assembly layer is provided on the lower electrode layer and includes a plurality of fine conductors assembled via a gap. The protective layer is provided on the nanomaterial assembly layer, is conductive, is in contact with the fine conductors, and includes an opening. The upper electrode layer is provided on the protective layer and is in contact with the protective layer.

### CROSS-REFERENCE TO RELATED APPLICATIONS

This application is based upon and claims the benefit of priority from the prior Japanese Patent Application No. 2011-031326, filed on Feb. 16, 2011; the entire contents of which are incorporated herein by reference.

### FIELD

Embodiments described herein relate generally to a memory device and a method for manufacturing the same.

### BACKGROUND

It has recently been discovered that a specific metal oxide material under application of a voltage exhibits two states, i.e., low resistance state and high resistance state, depending on the resistivity before the voltage application and on the magnitude of the applied voltage. A novel nonvolatile memory device based on this phenomenon is drawing attention. This nonvolatile memory device is called ReRAM (resistance random access memory). As an actual device structure for the ReRAM, from the viewpoint of increasing the memory density, a three-dimensional cross-point structure is proposed. In this structure, a memory cell is located at each cross-point of the word line (WL) and the bit line (BL). Even in ReRAM, still higher memory density is required.

### BRIEF DESCRIPTION OF THE DRAWINGS

FIG. 1 is a perspective view illustrating a nonvolatile memory device according to a first embodiment;

FIG. 2 is a sectional view illustrating a pillar of the nonvolatile memory device according to the first embodiment;

FIG. 3 to FIG. 6 are process sectional views illustrating a method for manufacturing the nonvolatile memory device according to the first embodiment;

FIG. 7 to FIG. 10 are process sectional views illustrating a method for manufacturing a nonvolatile memory device according to a comparative example;

FIG. 11 is a sectional view illustrating a pillar of a nonvolatile memory device according to a second embodiment;

FIG. 12 is a sectional view illustrating a pillar of a nonvolatile memory device according to a third embodiment;

FIG. 13 is a process sectional view illustrating a method for manufacturing the nonvolatile memory device according to the third embodiment; and

FIG. 14 is a sectional view illustrating a pillar of a nonvolatile memory device according to a fourth embodiment.

### DETAILED DESCRIPTION

In general, according to one embodiment, a memory device includes a lower electrode layer, a nanomaterial assembly layer, a protective layer and an upper electrode layer. The nanomaterial assembly layer is provided on the lower electrode layer and includes a plurality of fine conductors assembled via a gap. The protective layer is provided on the nanomaterial assembly layer, is conductive, is in contact with the fine conductors, and includes an opening. The upper electrode layer is provided on the protective layer and is in contact with the protective layer.

In general, according to one embodiment, a method is disclosed for manufacturing a memory device. The method can include forming a nanomaterial assembly layer on a lower electrode layer. The nanomaterial assembly layer includes a plurality of fine conductors assembled via a gap. The method can include forming a protective layer by depositing a protective material from above on the nanomaterial assembly layer. The protective layer is in contact with the fine conductors and includes an opening. The method can include depositing a filler material to bury the filler material in the gap through the opening and to bury the protective layer with the filler material. The method can include exposing the protective layer by removing a part of the filler material from above. In addition, the method can include forming an upper electrode layer on the protective layer.

Various embodiments will be described hereinafter with reference to the accompanying drawings.

First, a first embodiment is described.

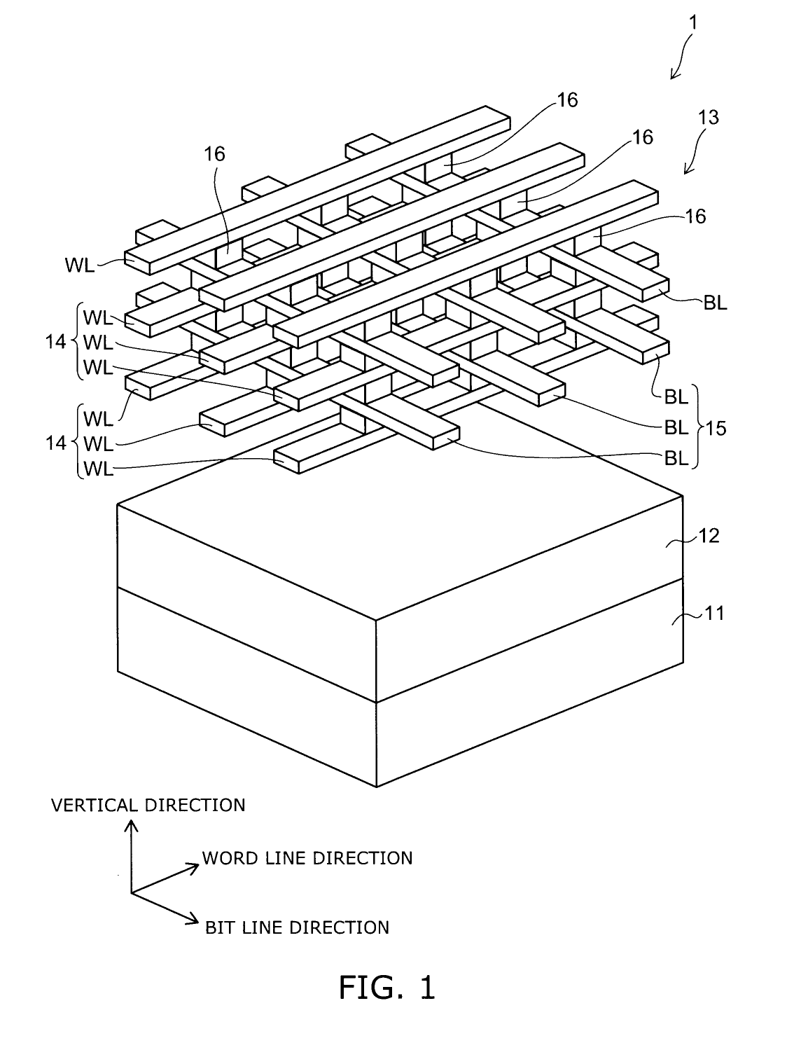

FIG. 1 is a perspective view illustrating a nonvolatile memory device according to the embodiment.

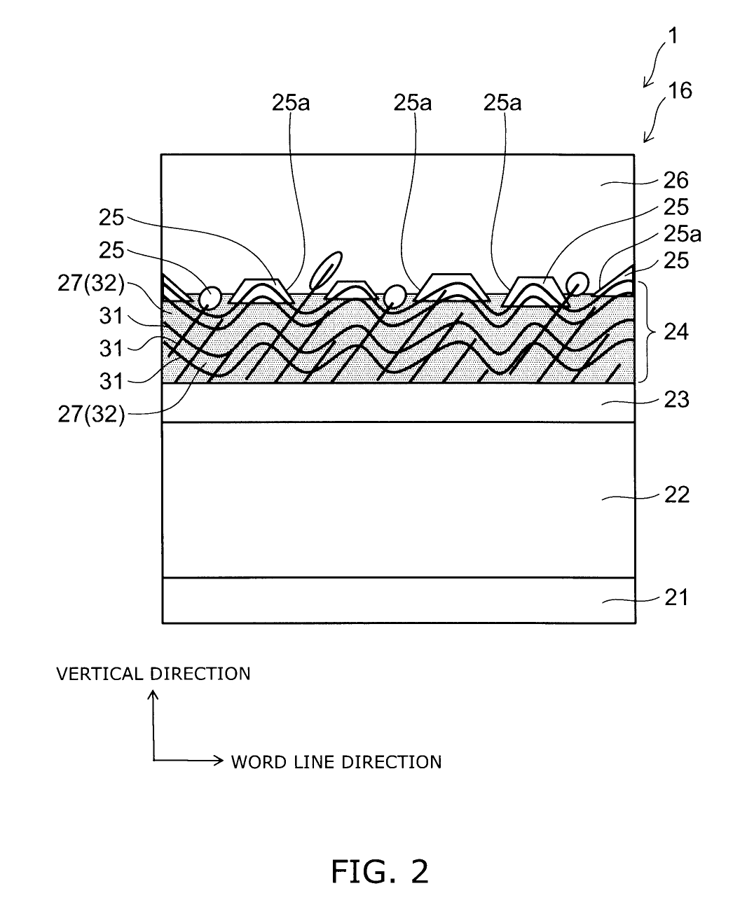

FIG. 2 is a sectional view illustrating a pillar of the nonvolatile memory device according to the embodiment.

The nonvolatile memory device according to the embodiment is a ReRAM.

As shown in FIG. 1, the nonvolatile memory device 1 according to the embodiment includes a silicon substrate 11. A driver circuit (not shown) for the nonvolatile memory device 1 is formed in an upper portion and on the upper surface of the silicon substrate 11. An interlayer insulating film 12 made of e.g. silicon oxide is provided on the silicon substrate 11 so as to bury the driver circuit. A memory cell unit 13 is provided on the interlayer insulating film 12.

In the memory cell unit 13, word line interconnection layers 14 and bit line interconnection layers 15 are alternately stacked via insulating layers. The word line interconnection layer 14 includes a plurality of word lines WL extending in one direction (hereinafter referred to as “word line direction”) parallel to the upper surface of the silicon substrate 11. The bit line interconnection layer 15 includes a plurality of bit lines BL extending in a direction (hereinafter referred to as “bit line direction”) being parallel to the upper surface of the silicon substrate 11 and crossing, such as being orthogonal to, the word line direction. The word lines WL, the bit lines BL, and the word line WL and the bit line BL are not in contact with each other.

At the nearest point of each word line WL and each bit line BL, a pillar 16 extending in the direction (hereinafter referred to as “vertical direction”) perpendicular to the upper surface of the silicon substrate 11 is provided. The pillar 16 is formed between the word line WL and the bit line BL. One pillar 16 constitutes one memory cell. That is, the nonvolatile memory device 1 is a cross-point device in which a memory cell is located at each nearest point of the word line WL and the bit line BL. An interlayer insulating film (not shown) is buried among the word lines WL, the bit lines BL, and the pillars 16.

In the following, the configuration of the pillar 16 is described with reference to FIG. 2.

As shown in FIG. 2, in each pillar 16, from bottom to top, a barrier metal layer 21, a silicon diode layer 22, a lower electrode layer 23, a nanomaterial assembly layer 24, a protective layer 25, and an upper electrode layer 26 are stacked in this order. As described later, a filler material 27 penetrates into the nanomaterial assembly layer 24. The barrier metal layer 21 is in contact with e.g. a word line WL (see FIG. 1). The upper electrode layer 26 is in contact with e.g. a bit line BL (see FIG. 1). A sidewall (not shown) made of e.g. silicon nitride is provided on the side surface of the pillar 16.

The barrier metal layer 21 is made of e.g. titanium nitride (TiN) or tantalum nitride (TaN). The silicon diode layer 22 is made of e.g. polysilicon in which, sequentially from bottom, an n-type layer having n⁺-type conductivity, an i-type layer made of an intrinsic semiconductor, and a p-type layer having p⁺-type conductivity are stacked. Thus, the silicon diode layer 22 functions as a select element which passes a current only when, for instance, the bit line BL is supplied with a higher potential than the word line WL, and which does not pass the current in the opposite direction. The lower electrode layer 23 is formed from a conductive material such as tungsten (W), titanium nitride (TiN), tungsten nitride (WN), tantalum nitride (TaN), or titanium silicide (TiSi).

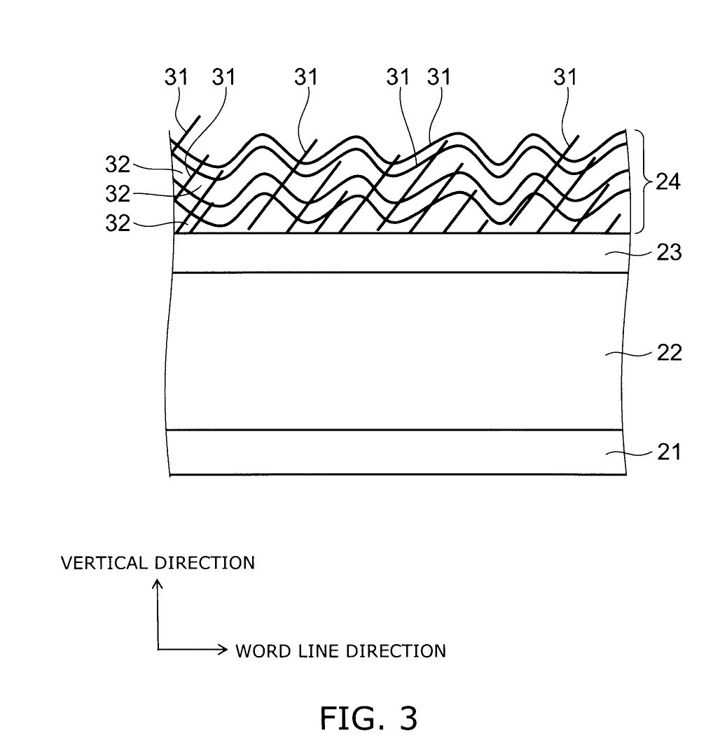

The nanomaterial assembly layer 24 is a layer in which CNTs (carbon nanotubes) 31 as fine conductors are assembled via gaps 32. In FIG. 2, CNTs 31 are schematically shown by lines or curves. This also applies to FIG. 3 and the following figures described later. The number of layers of CNTs 31 stacked in the thickness direction of the nanomaterial assembly layer 24 is e.g. approximately several to several ten layers. In the gap 32, an insulative filler material 27 is buried. The filler material 27 is e.g. silicon oxide. The upper portion of the CNT 31 protrudes from the upper surface of the deposition layer made of the filler material 27, and is not covered with the filler material 27. For instance, in the case where the CNT 31 extends generally linearly in the vertical or similar direction, the upper portion of the CNT 31 refers to the upper end portion of the CNT 31. In the case where the CNT 31 undulates and extends generally horizontally, the upper portion of the CNT 31 refers to the portion curved convex upward in the CNT 31 located in the upper portion of the nanomaterial assembly layer 24.

The protective layer 25 is provided on the nanomaterial assembly layer 24 and separately covers the aforementioned upper portion of the CNT 31. The protective layer 25 is made of a conductive material such as tungsten (W), titanium nitride (TiN), tungsten nitride (WN), tantalum nitride (TaN), or titanium silicide (TiSi). The protective layer 25 is formed so as to be in contact with the upper portion of the CNT 31 and to separately enclose the upper portion of the CNT 31. The protective layer 25 covering each CNT 31 is attached thereto more thickly toward the upper portion of the CNT 31. The attached protective layer 25 becomes thinner toward the lower portion of the CNT 31. On the still lower portion of the CNT 31, only metal fine particles are attached to the surface of the CNT 31. On the still lower portion, no protective layer 25 is attached. Such a distribution of the protective layer 25 can be confirmed by detecting the protective material using EDS (energy dispersive X-ray spectroscopy) or EELS (electron energy loss spectroscopy). The protective layer 25 is a discontinuous layer, and a plurality of openings 25a are distributed throughout the layer. The average thickness of the protective layer 25 is e.g. 5-20 nm.

The upper electrode layer 26 is formed from a conductive material similar to that of the lower electrode layer 23, such as tungsten (W), titanium nitride (TiN), tungsten nitride (WN), tantalum nitride (TaN), or titanium silicide (TiSi). The upper electrode layer 26 is provided on the protective layer 25 and is in contact with the protective layer 25. Hence, the upper electrode layer 26 is connected to the CNTs 31 through the protective layer 25. Furthermore, the upper electrode layer 26 enters into the openings 25a of the protective layer 25. Thus, the upper electrode layer 26 separately covers the portion of the protective layer 25 covering each CNT 31. Furthermore, the upper electrode layer 26 is in contact with the filler material 27 in the openings 25a. This interface of the upper electrode layer 26 and the filler material 27 is flat. Here, the protective layer 25 and the upper electrode layer 26 may be made of the same type of material, and the interface therebetween may be obscure. In this case, flat regions occur at the interface between the filler material 27 and the conductive layer made of the protective layer 25 and the upper electrode layer 26. This flat region is the region located inside the opening 25a. However, the shape of this region is affected by the CNT 31.

Next, a method for manufacturing a nonvolatile memory device according to the embodiment is described.

FIG. 3 to FIG. 6 are process sectional views illustrating the method for manufacturing a nonvolatile memory device according to the embodiment.

First, as shown in FIG. 1, a driver circuit for driving the memory cell unit 13 is formed in the upper surface of a silicon substrate 11. Next, an interlayer insulating film 12 is formed on the silicon substrate 11. Next, contacts (not shown) extending to the driver circuit are formed in the interlayer insulating film 12. Next, tungsten is buried in an upper portion of the interlayer insulating film 12 by e.g. the damascene method. Thus, a plurality of word lines WL are formed parallel to each other so as to extend in the word line direction. These word lines WL form a word line interconnection layer 14.

Next, as shown in FIG. 3, titanium nitride (TiN), for instance, is deposited on the word line interconnection layer 14 (see FIG. 1) to form a barrier metal layer 21. Next, amorphous silicon is deposited on the barrier metal layer 21. Here, while depositing amorphous silicon, impurities are introduced to continuously form an n-type layer, an i-type layer, and a p-type layer. The barrier metal layer 21 is a barrier layer for suppressing reaction between tungsten forming the word line WL and silicon forming the silicon diode layer 22. Next, on the silicon diode layer 22, a conductive material such as tungsten (W), titanium nitride (TiN), tungsten nitride (WN), tantalum nitride (TaN), or titanium silicide (TiSi) is deposited to form a lower electrode layer 23.

Next, a dispersion liquid with CNTs 31 dispersed in water is applied onto the lower electrode layer 23, and dried. In the process in which the dispersion liquid is dried and the thickness is decreased, the extending direction of the CNTs 31 is made close to the horizontal direction, i.e., the direction parallel to the plane formed by the word line direction and the bit line direction. Thus, a nanomaterial assembly layer 24 is formed. Here, the above applying and drying may be repeated a plurality of times. In the nanomaterial assembly layer 24, a plurality of CNTs 31 are loosely coupled to each other, and gaps 32 are formed between the CNTs 31.

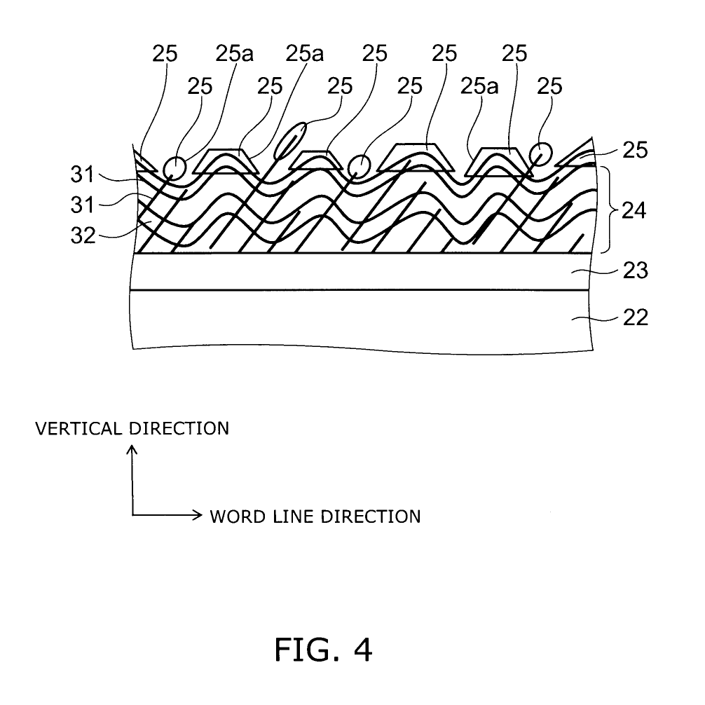

Next, as shown in FIG. 4, from above the nanomaterial assembly layer 24, a conductive material such as tungsten (W), tungsten nitride (WN), titanium nitride (TiN), and tantalum nitride (TaN) is deposited as a protective material. Thus, a protective layer 25 is formed on the nanomaterial assembly layer 24. This deposition of the protective material is performed by a method with decreased coverage, such as vapor phase deposition, to form the protective layer 25 as a discontinuous layer. For instance, a discontinuous layer made of the protective material can be formed by performing PVD (physical vapor deposition) or CVD (chemical vapor deposition) with the amount of deposition limited to e.g. 5-20 nm.

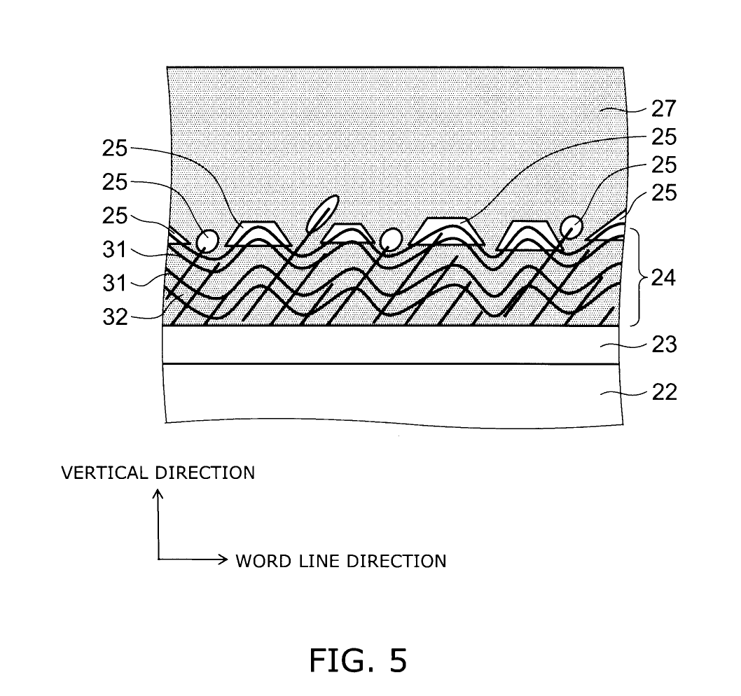

In general, if a metal is sufficiently thinly deposited on the CNT, a film of the metal is formed so as to separately enclose the surface of the CNT. Hence, the protective layer 25 is formed so as to be in contact with the upper portion of the CNT 31 and to separately enclose the upper portion of the CNT 31. Furthermore, by limiting the amount of deposition of the protective material, the protective layer 25 is formed as a discontinuous layer, and a plurality of openings 25a are formed throughout the layer. The size of the opening 25a is set so that in the process of depositing a filler material 27 described below (see FIG. 5), the filler material 27 extends into the entirety of the nanomaterial assembly layer 24 through the openings 25a. Here, the protective material is deposited by a method with low coverage. Hence, the protective material does not penetrate deeply into the gaps 32 of the nanomaterial assembly layer 24, but most of the gaps 32 are left hollow.

Next, as shown in FIG. 5, a liquid insulative filler material 27 is applied. Here, the amount of application of the filler material 27 is made sufficiently thicker than the total film thickness of the nanomaterial assembly layer 24 and the protective layer 25. Thus, the filler material 27 is buried in the entirety of the gaps 32 of the nanomaterial assembly layer 24 through the openings 25a of the protective layer 25. Furthermore, the filler material 27 is located also on the nanomaterial assembly layer 24 and buries the protective layer 25. The filler material 27 can be made of e.g. a solution of SOD (spin on dielectric) dissolved in an organic solvent, such as “SILK” manufactured by The Dow Chemical Company (“SILK” is a trademark of The Dow Chemical Company). Thus, the burying with the filler material 27 is performed by a method with higher coverage than the aforementioned deposition of the protective material, such as the coating method.

Next, the filler material 27 is solidified. For instance, in the case where “SiLK” is used as the filler material 27, the filler material 27 is solidified by heating to a temperature of 450° C. The solidified filler material 27 is buried in the gaps 32 of the nanomaterial assembly layer 24, covers the protective layer 25, and is thickly formed also on the protective layer 25.

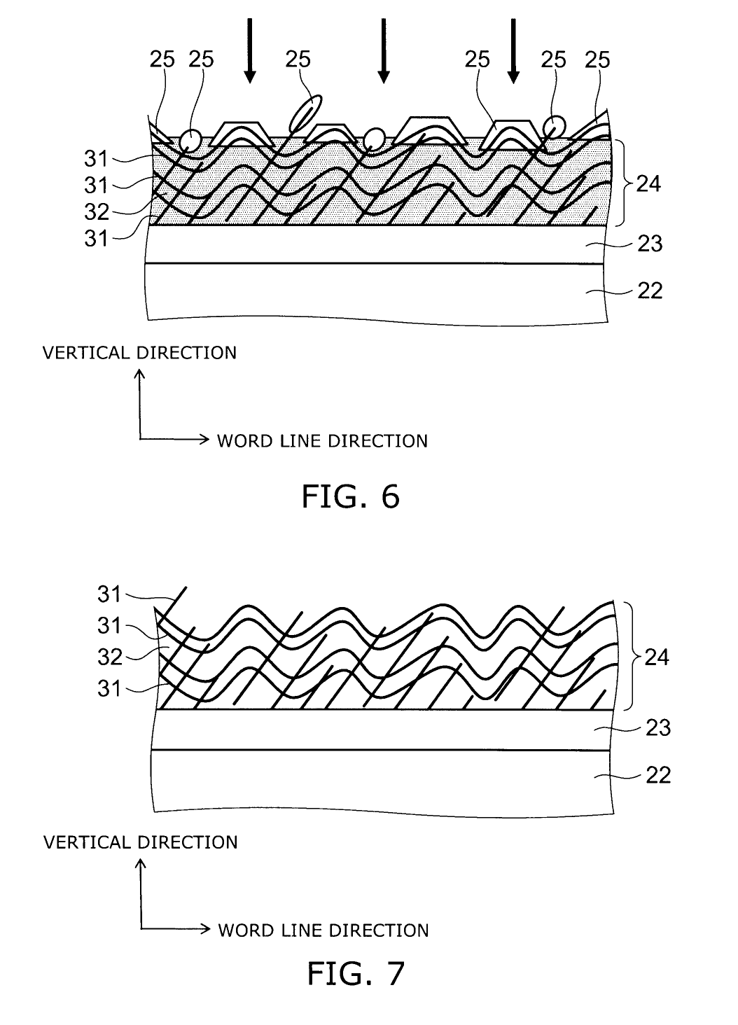

Next, as shown in FIG. 6, dry etching such as RIE (reactive ion etching) is performed from above. This dry etching is performed under a condition such that the etching rate of the filler material 27 is higher than the etching rate of the protective layer 25. Furthermore, in the exhaust gas of the dry etching, the presence or absence of the protective material is detected. If the protective material is detected in the exhaust gas, the dry etching is stopped. Thus, the upper portion of the filler material 27 is removed, and the protective layer 25 is exposed. Here, the filler material 27 is selectively etched with respect to the protective layer 25. Hence, the upper surface of the filler material 27 located in the opening 25a of the protective layer 25 is made lower than the upper surface of the protective layer 25. Thus, the protective layer 25 protrudes from the upper surface of the deposition layer of the filler material 27. Furthermore, the upper portion of the CNTs 31 is covered with the protective layer 25, and hence is not exposed to the etching gas. Thus, the upper portion of the CNTs 31 is protected from the etching. Furthermore, the portion of the CNTs 31 other than the upper portion is covered with the filler material 27, and hence is also protected from the etching.

Next, as shown in FIG. 2, from above the protective layer 25, a conductive material such as tungsten (W), titanium nitride (TiN), tungsten nitride (WN), tantalum nitride (TaN), or titanium silicide (TiSi) is deposited. This deposition is performed at a temperature such as not to destroy the filler material 27. For instance, in the case where “SiLK” (trademark of The Dow Chemical Company) is used as the filler material 27, the vaporization temperature of this material is approximately 600° C. Hence, the above deposition of the conductive material is performed at a temperature lower than 600° C.

Thus, an upper electrode layer 26 is formed on the protective layer 25. The upper electrode layer 26 covers the protective layer 25 and is in contact with the protective layer 25. Furthermore, the upper electrode layer 26 enters into the openings 25a of the protective layer 25 and is brought into contact with the filler material 27. On the other hand, in the gaps 32 of the nanomaterial assembly layer 24, the filler material 27 has already been buried. Hence, the upper electrode layer 26 does not penetrate into the gaps 32. Thus, the surface roughness of the lower surface of the upper electrode layer 26 in the opening 25a is made comparable to the surface roughness of the upper surface of the filler material 27.

Next, a hard mask (not shown) is formed on the upper electrode layer 26, and a resist film (not shown) is formed. Next, by exposure and development, the resist film is patterned to form a resist pattern. Next, this resist pattern is used as a mask to pattern the hard mask. Next, the patterned hard mask is used as a mask to perform anisotropic etching such as RIE. Thus, the upper electrode layer 26, the protective layer 25, the nanomaterial assembly layer 24, the lower electrode layer 23, the silicon diode layer 22, and the barrier metal layer 21 are selectively removed and divided along both the word line direction and the bit line direction. Accordingly, pillars 16 (see FIG. 1) are formed.

Next, silicon nitride is deposited by e.g. the CVD method to form a liner film (not shown) on the upper surface and side surface of the pillar 16. Next, an insulating material is deposited to form an interlayer insulating film (not shown) so that the pillar 16 is buried therein. Next, the upper electrode layer 26 is used as a stopper to perform CMP (chemical mechanical polishing) treatment. Thus, the upper surface of the interlayer insulating film is planarized, and the upper electrode layer 26 is exposed at the upper surface of the interlayer insulating film. Accordingly, the portion of the liner film left on the side surface of the pillar 16 constitutes a sidewall.

Next, as shown in FIG. 1, on the interlayer insulating film, another interlayer insulating film (not shown) is formed, and bit lines BL are formed by e.g. the damascene method. The bit line BL is formed from e.g. tungsten. These bit lines BL form a bit line interconnection layer 15. Each bit line BL is connected to the upper surface of a plurality of pillars 16 arranged in the bit line direction. Thus, each pillar 16 is formed between the word line WL and the bit line BL, and connected to the word line WL and the bit line BL.

Next, pillars 16 are formed on the bit line BL. In forming this pillar 16, the stacking order of the n-type layer, the i-type layer, and the p-type layer in the silicon diode layer 22 is reversed with respect to the aforementioned pillar 16 formed on the word line WL. Subsequently, by a similar method, a word line interconnection layer 14, a plurality of pillars 16, a bit line interconnection layer 15, and a plurality of pillars 16 are formed repetitively. Thus, the nonvolatile memory device 1 according to the embodiment is manufactured.

Next, the operation of the embodiment is described.

In the nonvolatile memory device 1 according to the embodiment, the nanomaterial assembly layer 24 can have two states, i.e., “high resistance state” and “low resistance state”. Although this mechanism is not necessarily clear, it may be attributable to the change of the connection state between the lower electrode layer 23 and the CNT 31. By applying a prescribed voltage between the lower electrode layer 23 and the upper electrode layer 26, these two states can be switched. Thus, binary data associated with the respective states can be stored.

Next, the effect of the embodiment is described.

According to the embodiment, a filler material 27 is buried in the gaps 32 of the nanomaterial assembly layer 24. Thus, the mechanical strength of the nanomaterial assembly layer 24 is made higher than in the case without the filler material 27. When the nanomaterial assembly layer 24 and the like are patterned to form pillars 16, the pillars 16 can be prevented from collapsing or fracturing with the nanomaterial assembly layer 24 acting as a fracture surface. Thus, the pillar 16 can be slimmed to increase the memory density of memory cells.

Furthermore, according to the embodiment, after the filler material 27 is buried in the gaps 32 of the nanomaterial assembly layer 24, a conductive material is deposited to form an upper electrode layer 26. Thus, the upper electrode layer 26 can be formed while preventing the conductive material from penetrating into the gaps 32 of the nanomaterial assembly layer 24. Here, the protective layer 25 is formed when the filler material 27 is not buried. However, the protective layer 25 is deposited under the condition of low coverage. Hence, the protective material does not penetrate deeply into the nanomaterial assembly layer 24. As a result, the lower surface of the upper electrode layer 26 can be flattened, and the film thickness of the nanomaterial assembly layer 24 can be made uniform. Hence, the electrical characteristics of memory cells can be stabilized. Thus, even if the pillars 16 are finely processed, the characteristics variation of memory cells can be suppressed. In other words, the memory density of memory cells can be increased while limiting the characteristics variation of the memory cells within a prescribed range.

Furthermore, in the embodiment, a conductive protective layer 25 is in contact with the upper portion of the CNTs 31, and the upper electrode layer 26 is in contact with the protective layer 25. The upper portion of the CNTs 31 is covered with the protective layer 25. Hence, the contact area between the CNT 31 and the protective layer 25 is large. Furthermore, the process of etching the filler material 27 shown in FIG. 6 is performed under a condition such that the etching rate of the filler material 27 is sufficiently higher than the etching rate of the protective layer 25. Thus, the protective layer 25 is left in the form of protruding upward from the upper surface of the deposition layer of the filler material 27. Subsequently, a conductive material is deposited to form an upper electrode layer 26. Thus, each portion of the protective layer 25 is enclosed with the upper electrode layer 26. Hence, the contact area between the protective layer 25 and the upper electrode layer 26 is also made large. Thus, the current path between the CNT 31 and the upper electrode layer 26 is made thicker and more robust than in the case without the protective layer 25.

Furthermore, without the protective layer 25, some of the CNTs 31 may fail to be in contact with the upper electrode layer 26. However, by forming the protective layer 25, such CNTs 31 are also connected to the upper electrode layer 26 through the protective layer 25. Thus, the number of CNTs 31 connected to the upper electrode layer 26 can be made larger than in the case without the protective layer 25. As a result, the CNTs 31 can be reliably connected to the upper electrode layer 26 even if the pillars 16 are slimmed to increase the memory density of memory cells.

Moreover, in the embodiment, the protective layer 25 covers the upper portion of the CNTs 31. Hence, in etching the filler material 27 in the process shown in FIG. 6, the CNTs 31 can be prevented from being exposed to the etching gas. This can protect the CNTs 31 and prevent the CNTs 31 from being damaged by etching. As a result, the characteristics degradation of memory cells due to such damage can be prevented.

Moreover, in the embodiment, in etching the filler material 27 in the process shown in FIG. 6, the presence or absence of the protective material in the exhaust gas is detected. If the protective material is detected, the etching is stopped. Thus, the etching can be accurately stopped when the protective layer 25 is exposed. As a result, the amount of CNTs 31 removed by this etching can be suppressed, and the material cost can be reduced.

Next, a comparative example is described.

FIG. 7 to FIG. 10 are process sectional views illustrating a method for manufacturing a nonvolatile memory device according to the comparative example.

The comparative example is different from the above first embodiment in not forming the protective layer 25.

First, as shown in FIG. 1, by a method similar to that of the above first embodiment, a driver circuit is formed in the upper surface of a silicon substrate 11. Then, an interlayer insulating film 12 is formed, and a word line interconnection layer 14 is formed.

Next, as shown in FIG. 7, a barrier metal layer 21 (see FIG. 3), a silicon diode layer 22, a lower electrode layer 23, and a nanomaterial assembly layer 24 are formed.

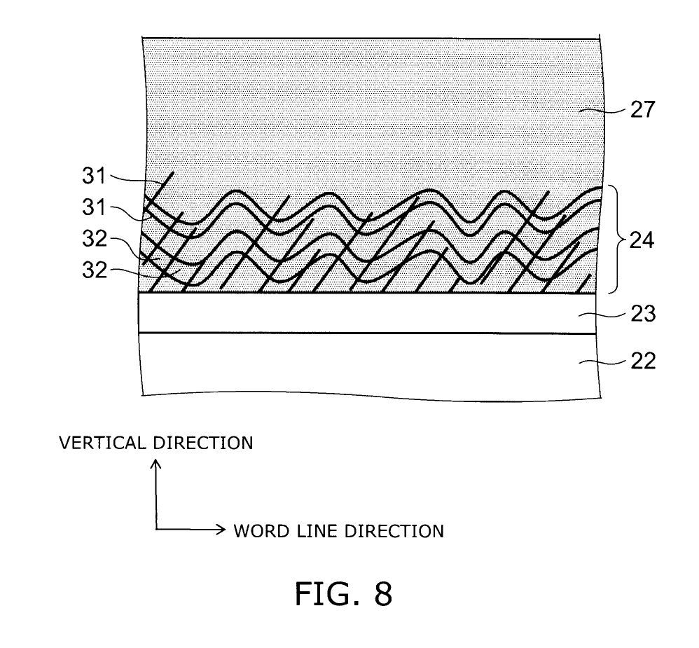

Next, as shown in FIG. 8, without forming a protective layer 25 (see FIG. 4), a filler material 27 is applied and solidified. The filler material 27 is buried in the gaps 32 of the nanomaterial assembly layer 24, and located also on the nanomaterial assembly layer 24.

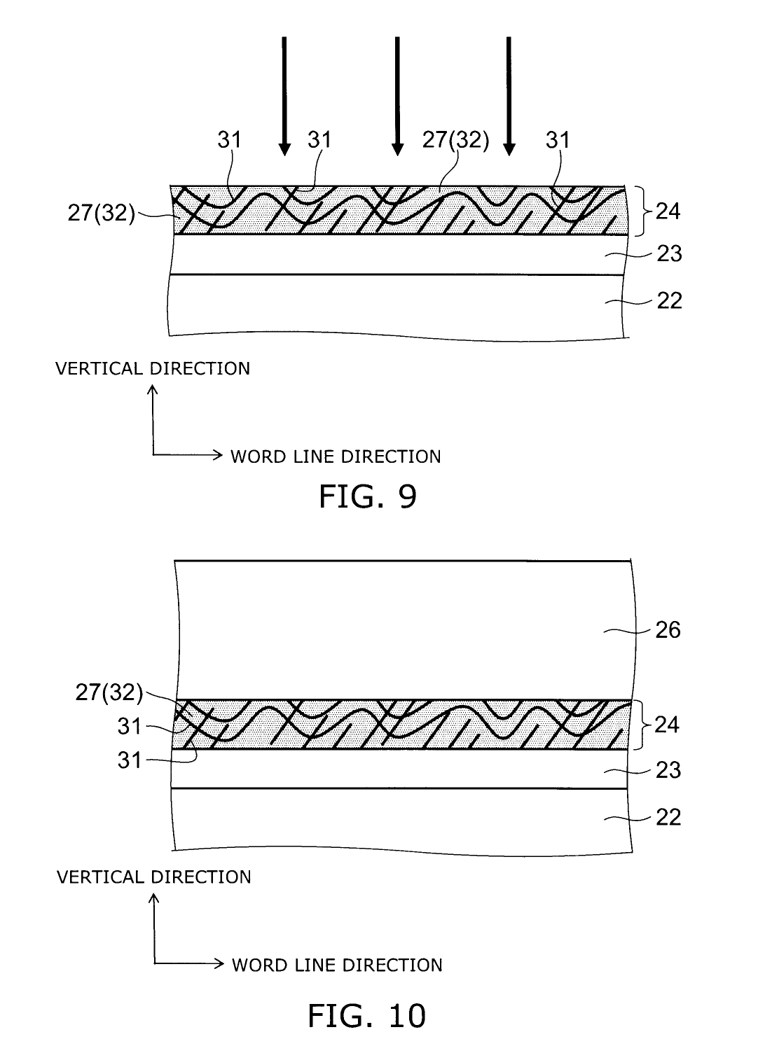

Next, as shown in FIG. 9, dry etching such as RIE is performed from above to remove the upper portion of the filler material 27 and to expose the CNTs 31. In this dry etching, after the etching surface reaches the nanomaterial assembly layer 24, the CNTs 31 are also etched together with the filler material 27. Hence, the upper surface of the nanomaterial assembly layer 24 is flattened. However, it is impossible to detect when the etching surface reaches the nanomaterial assembly layer 24. Hence, to ensure that the CNTs 31 are exposed, the etching is performed with slight overetching.

Next, as shown in FIG. 10, a conductive material is deposited on the exposed nanomaterial assembly layer 24 to form an upper electrode layer 26. Here, the interface of the nanomaterial assembly layer 24 and the upper electrode layer 26 is flattened. The CNTs 31 are in contact with the lower surface of the upper electrode layer 26 at this interface. The subsequent process is similar to that of the above first embodiment.

In the comparative example, in the process shown in FIG. 9, etching needs to be performed with slight overetching to ensure that the CNTs 31 are exposed. However, this results in losing part of the CNTs 31. Thus, in consideration of this amount of loss, the nanomaterial assembly layer 24 needs to be thickly formed in advance. This increases the material cost. In contrast, according to the above first embodiment, etching is performed while detecting the protective material. Thus, the etching can be stopped when the protective layer 25 is exposed. Hence, the loss of CNTs 31 can be suppressed, and the material cost can be suppressed.

Furthermore, in the comparative example, in the process shown in FIG. 9, the CNTs 31 are also etched together with the filler material 27. Hence, the CNTs 31 are damaged. In contrast, according to the above first embodiment, etching is performed with the upper portion of the CNTs 31 covered with the protective layer 25. This can prevent the CNTs 31 from being damaged.

Furthermore, in the comparative example, the CNTs 31 in the nanomaterial assembly layer 24 are nearly in point contact with the lower surface of the upper electrode layer 26. Thus, the contact resistance between the CNT 31 and the upper electrode layer 26 is high and unstable. This makes the characteristics of memory cells unstable. This problem is made more conspicuous if the pillars 16 are slimmed to increase the memory density of memory cells. In contrast, according to the above first embodiment, the upper portion of the CNTs 31 is covered with a conductive protective layer 25, and the protective layer 25 is covered with the upper electrode layer 26. Hence, the current path between the CNT 31 and the upper electrode layer 26 is thick and robust. Thus, the contact resistance between the CNT 31 and the upper electrode layer 26 is low and stable.

Here, if the protective layer 25 is not formed and the filler material 27 is not applied, the conductive material penetrates deeply into the gaps 32 of the nanomaterial assembly layer 24 when the upper electrode layer 26 is formed. Thus, the mixed layer of the CNT 31 and the upper electrode layer 26 are thickened. For instance, the mixed layer having a thickness of 20-50 nm is formed. In contrast, in the above first embodiment, the thickness of the mixed layer is approximately 5-20 nm. This can be confirmed by observing the cross section of a sample using TEM (transmission electron microscopy).

Next, a second embodiment is described.

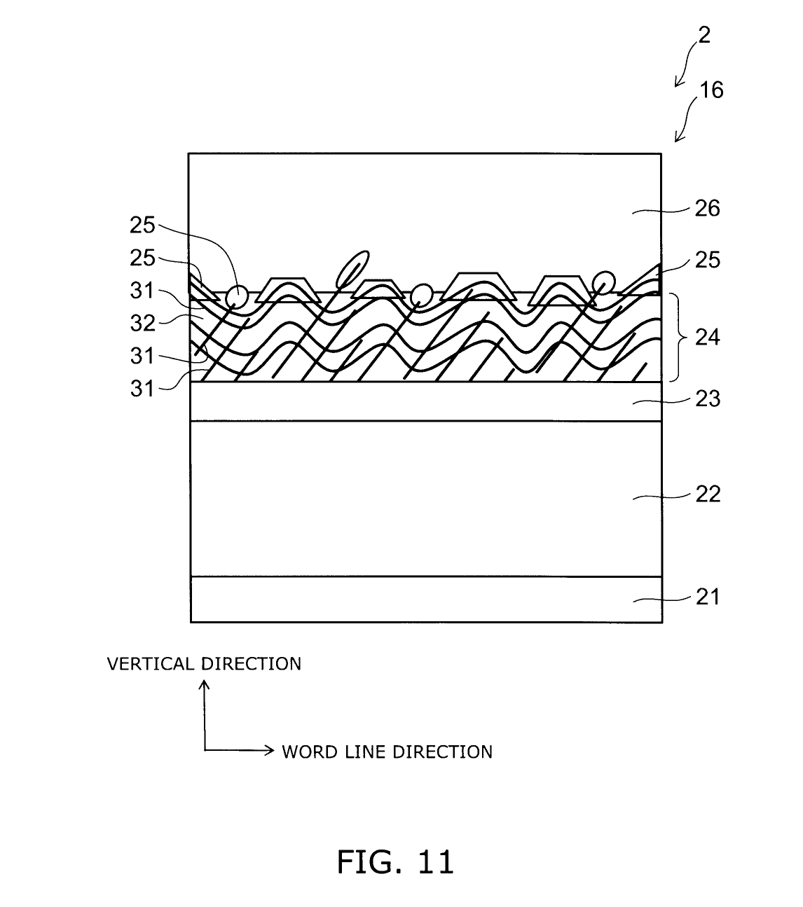

FIG. 11 is a sectional view illustrating a pillar of a nonvolatile memory device according to the embodiment.

As shown in FIG. 11, the nonvolatile memory device 2 according to the embodiment is different from the nonvolatile memory device 1 (see FIG. 2) according to the above first embodiment in that the filler material 27 (see FIG. 2) is not buried in the nanomaterial assembly layer 24.

Next, a method for manufacturing a nonvolatile memory device according to the embodiment is described.

First, in the method described in the above first embodiment, the processes shown in FIG. 3 to FIG. 6 are performed. Next, as shown in FIG. 2, an upper electrode layer 26 is formed. Then, the upper electrode layer 26, the protective layer 25, the nanomaterial assembly layer 24 with the filler material 27 buried therein, the lower electrode layer 23, the silicon diode layer 22, and the barrier metal layer 21 are etched and processed into pillars 16. The process so far is similar to that of the above first embodiment.

Then, in the embodiment, after the pillars 16 are formed, the filler material 27 is removed. The filler material 27 can be removed by e.g. vaporization by heat treatment. For instance, in the case where the filler material 27 is formed from “SiLK” described above, “SILK” can be vaporized by heating to a temperature of 600° C. or more. Then, a sidewall is formed. The subsequent process is similar to that of the above first embodiment. Thus, the nonvolatile memory device 2 shown in FIG. 11 is manufactured.

In the nonvolatile memory device 2 according to the embodiment, in the lower surface of the upper electrode layer 26, the region located in the opening 25a of the protective layer 25 is not supported by the filler material 27 after the filler material 27 is removed. Thus, if the upper electrode layer 26 is deformed by the subsequent heat treatment, for instance, this region may become non-flat.

According to the embodiment, as compared with the above first embodiment, the mobility of each CNT 31 can be enhanced, and the switching rate can be increased. The configuration, manufacturing method, operation, and effect of the embodiment other than the foregoing are similar to those of the above first embodiment.

Next, a third embodiment is described.

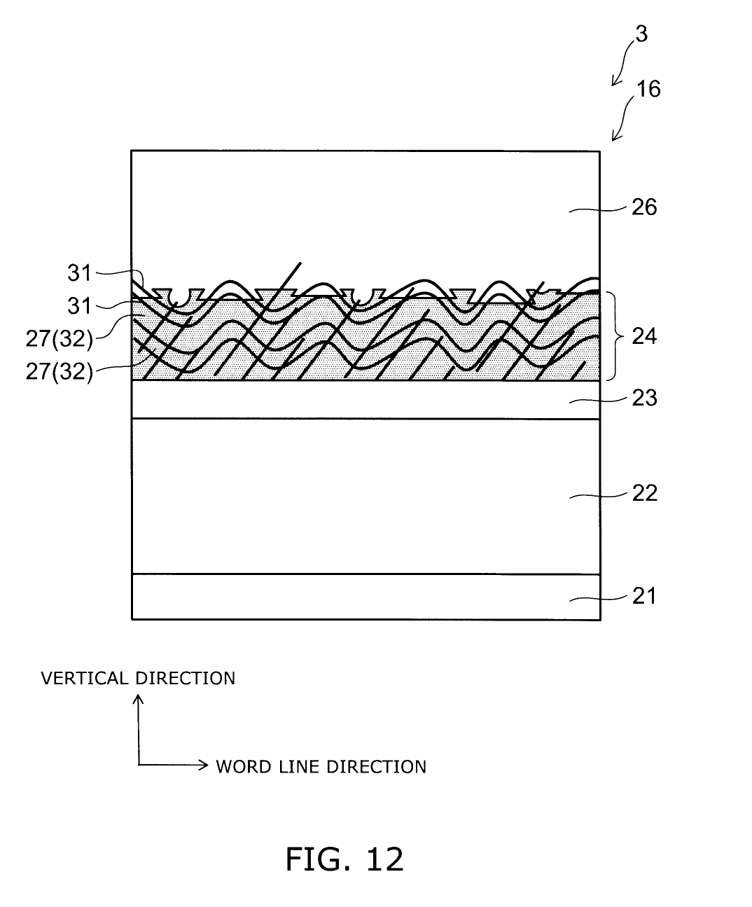

FIG. 12 is a sectional view illustrating a pillar of a nonvolatile memory device according to the embodiment.

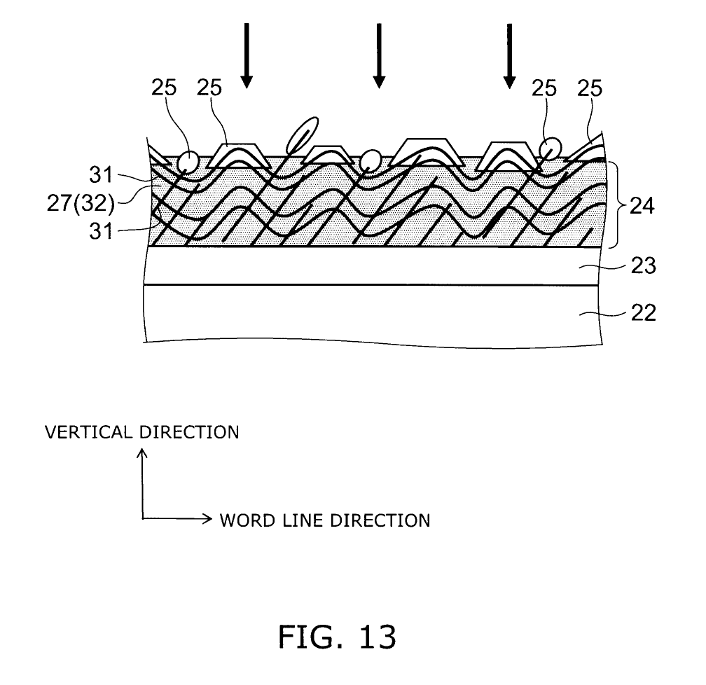

FIG. 13 is a process sectional view illustrating a method for manufacturing a nonvolatile memory device according to the embodiment.

As shown in FIG. 12, the nonvolatile memory device 3 according to the embodiment is different from the nonvolatile memory device 1 (see FIG. 2) according to the above first embodiment in that the protective layer 25 is not provided. However, as described below, the protective layer 25 is formed in the process of manufacturing the nonvolatile memory device 3.

Next, a method for manufacturing a nonvolatile memory device according to the embodiment is described.

First, the processes shown in FIG. 3 to FIG. 6 are performed. Here, silicon nitride (SiN) is used as the material of the protective layer 25 (protective material). Next, as shown in FIG. 13, etching is performed under a condition such that the etching rate of the protective layer 25 is higher than the etching rate of the filler material 27. For instance, wet etching using phosphoric acid as an etching liquid is performed. Thus, the protective layer 25 is removed. Here, a recess is formed in the region of the upper surface of the deposition layer of the filler material 27 from which the protective layer 25 has been removed. Primarily in this recess, the upper portion of the CNT 31 previously covered with the protective layer 25 is exposed. Subsequently, as shown in FIG. 12, an upper electrode layer 26 is formed on the nanomaterial assembly layer 24. Here, the upper electrode layer 26 is buried also in the recess and covers the exposed portion of the CNT 31. The subsequent process is similar to that of the above first embodiment. Thus, the nonvolatile memory device 3 shown in FIG. 12 is manufactured.

According to the embodiment, as compared with the above first embodiment, there is no need to limit the material of the protective layer 25 (protective material) to a conductive material. Insulating materials such as silicon nitride can also be used. This extends the range of choices of the protective material and facilitates manufacturing. For instance, in the embodiment, the protective layer 25 is formed from silicon nitride (SiN), and the etching liquid is phosphoric acid. However, the embodiment is not limited thereto. For instance, the protective layer 25 may be formed from tungsten (W), and the etching liquid may be NC2, i.e., a mixed solution of hydrogen peroxide water and TMY. Alternatively, the protective layer 25 may be formed from tungsten nitride (WN), and the etching liquid may be NC2. However, as the etching liquid, it is necessary to select a liquid which does not damage the CNTs 31 and the surrounding material.

Also in the embodiment, in etching the filler material 27 in the process shown in FIG. 6, CNTs 31 are covered with the protective layer 25. Hence, damage to the CNTs 31 can be prevented. Furthermore, in etching the filler material 27, by detecting the material of the protective layer 25 (protective material), the etching can be accurately stopped to prevent excessive etching of the nanomaterial assembly layer 24. Moreover, the upper electrode layer 26 is formed so as to cover the upper portion of each CNT 31. Hence, the contact area between the CNT 31 and the upper electrode layer 26 is made large, and the contact resistance can be reduced. The configuration, manufacturing method, operation, and effect of the embodiment other than the foregoing are similar to those of the above first embodiment.

Next, a fourth embodiment is described.

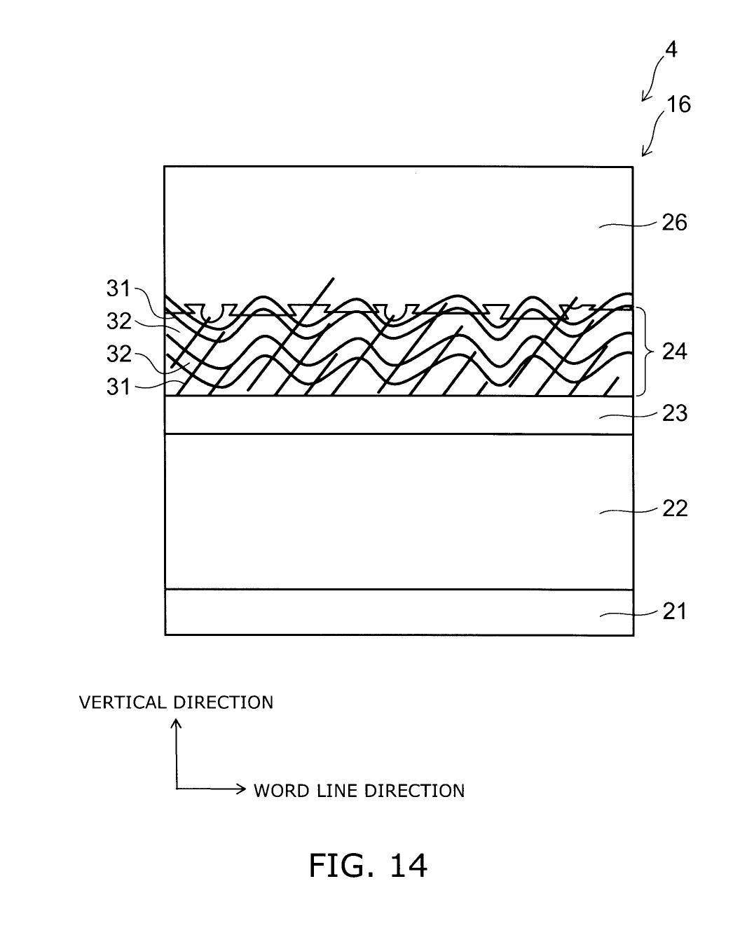

FIG. 14 is a sectional view illustrating a pillar of a nonvolatile memory device according to the embodiment.

As shown in FIG. 14, the embodiment is a combination of the second embodiment and the third embodiment described above. That is, the nonvolatile memory device 4 according to the embodiment is different from the nonvolatile memory device 1 (see FIG. 2) according to the above first embodiment in that the protective layer 25 and the filler material 27 are not provided.

Next, a method for manufacturing a nonvolatile memory device according to the embodiment is described.

First, the processes shown in FIG. 3 to FIG. 6 are performed. More specifically, a barrier metal layer 21, a silicon diode layer 22, a lower electrode layer 23, a nanomaterial assembly layer 24, and a protective layer 25 are formed in this order. A filler material 27 is deposited thereon. Then, the upper portion of the filler material 27 is removed to expose the protective layer 25. Next, as shown in FIG. 13, the protective layer 25 is removed by etching. Next, as shown in FIG. 14, an upper electrode layer 26 is formed. Next, the stacked film from the barrier metal layer 21 to the upper electrode layer 26 is etched and processed into pillars 16. Next, the filler material 27 is removed by e.g. vaporizing the filler material 27 by heat treatment. Next, a sidewall is formed on the side surface of the pillar 16. The subsequent process is similar to that of the above first embodiment. Thus, the nonvolatile memory device 4 shown in FIG. 14 is manufactured.

The effect of the embodiment is similar to that of the above second and third embodiments. The configuration, manufacturing method, and operation of the embodiment other than the foregoing are similar to those of the above first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

For instance, in the examples described in the above embodiments, CNTs (carbon nanotubes) are used as fine conductors constituting the nanomaterial assembly layer. However, the embodiments are not limited thereto. The fine conductor may be made of e.g. graphene, fullerene, carbon nanoribbon, carbon nanocoil, silicon nanotube, porous material, or a mixture thereof. Furthermore, the material of the lower electrode layer 23 and the upper electrode layer 26 is not limited to the examples described above, but may be selected depending on the material property such as conductivity characteristics and on the process convenience, for instance.

The embodiments described above can realize a memory device capable of increasing the memory density, and a method for manufacturing the same.

What is claimed is:

1. A memory device comprising:
a lower electrode layer;
a nanomaterial assembly layer provided on the lower electrode layer and including a plurality of fine conductors assembled via a gap;
a protective layer provided on the nanomaterial assembly layer, being conductive, being in contact with the fine conductors, and including an opening; and
an upper electrode layer provided on the protective layer and being in contact with the protective layer.

2. The device according to claim 1, further comprising:
an insulative filler material buried in the gap,
the upper electrode layer being in contact with the filler material through the opening.

3. The device according to claim 1, wherein the protective layer covers an upper portion of each of the fine conductors.

4. The device according to claim 1, wherein the upper electrode layer enters into the opening.

5. The device according to claim 1, wherein the fine conductors are carbon nanotubes.

6. The device according to claim 1, further comprising:
a word line interconnection layer including a plurality of word lines extending in a first direction; and
a bit line interconnection layer including a plurality of bit lines extending in a second direction crossing the first direction,
the word line interconnection layer and the bit line interconnection layer being alternately stacked, and
the lower electrode layer, the nanomaterial assembly layer, the protective layer, and the upper electrode layer being stacked between each of the word lines and each of the bit lines to form a pillar.

7. A method for manufacturing a memory device, comprising:
forming a nanomaterial assembly layer on a lower electrode layer, the nanomaterial assembly layer including a plurality of fine conductors assembled via a gap;
forming a protective layer by depositing a protective material from above on the nanomaterial assembly layer, the protective layer being in contact with the fine conductors and including an opening;
depositing a filler material to bury the filler material in the gap through the opening and to bury the protective layer with the filler material;
exposing the protective layer by removing a part of the filler material from above; and
forming an upper electrode layer on the protective layer.

8. The method according to claim 7, wherein
the exposing the protective layer includes dry etching the filler material while detecting presence or absence of the protective material in exhaust gas, and
based on a result of the detecting, the dry etching is stopped.

9. The method according to claim 7, wherein the depositing the filler material is performed by a method with higher coverage than the deposition of the protective material.

10. The method according to claim 9, wherein the depositing the filler material is performed by coating, and the depositing the protective material is performed by vapor phase deposition.

11. The method according to claim 7, wherein the protective material is a conductive material.

12. The method according to claim 7, further comprising:
removing the protective layer after the exposing the protective layer and before the forming the upper electrode layer.

13. The method according to claim 7, wherein the filler material is an insulating material.

14. The method according to claim 7, further comprising:
removing the filler material after the forming the upper electrode layer.

15. The method according to claim 7, wherein the fine conductors are carbon nanotubes.

16. The method according to claim 7, further comprising:
forming a word line interconnection layer including a plurality of word lines extending in a first direction; and
forming a bit line interconnection layer including a plurality of bit lines extending in a second direction crossing the first direction,
the forming the word line interconnection layer and the forming the bit line interconnection layer being alternately performed, and
the forming the nanomaterial assembly layer, the forming the protective layer, the depositing the filler material, the exposing the protective layer, and the forming the upper electrode layer being performed between the forming the word line interconnection layer and the forming the bit line interconnection layer.
